(19) United States
(12) Patent Application Publication
(10) Pub. No.: US 2014/0284798 A1
(43) Pub. Date: Sep. 25, 2014

(54) GRAPHENE WIRING AND METHOD OF MANUFACTURING THE SAME

(71) Applicant: Kabushiki Kaisha Toshiba, Minato-ku (JP)

(72) Inventors: Hisao MIYAZAKI, Kanagawa (JP); Tadashi Sakai, Kanagawa (JP); Masayuki Katagiri, Kanagawa (JP); Yuichi Yamazaki, Tokyo (JP); Mariko Suzuki, Kanagawa (JP)

(73) Assignee: Kabushiki Kaisha Toshiba, Minato-ku (JP)

(21) Appl. No.: 14/202,013

(22) Filed: Mar. 10, 2014

(30) Foreign Application Priority Data
Mar. 19, 2013 (JP) 2013-057006

(51) Int. Cl. H01L 23/532; H01L 21/285

(52) U.S. Cl. CPC H01L 23/53276; H01L 21/28506
USPC 257/750; 438/610

(57) ABSTRACT

A graphene wiring has a substrate a catalyst layer on the substrate a first graphene sheet layer on the catalyst layer and a second graphene sheet layer on the first graphene layer. The second graphene layer comprises multilayer graphene sheets. The multilayer graphene sheets are intercalated with an atomic or molecular species.

### CROSS-REFERENCE TO RELATED APPLICATION

This application is based upon and claims the benefit of priority from Japanese Patent Application No. 2013-057006 Mar. 19, 2013; the entire contents of which are incorporated herein by reference.

### FIELD

Embodiments described herein relate generally to a graphene wiring and a method of manufacturing the same.

### BACKGROUND

Increase in wiring delay in metal wiring with miniaturized multi-layered LSI and 3D memory is a large problem. In order to decrease the wiring delay, it is important to decrease wiring resistance and interwire capacitance. Application of a low-resistance material such as Cu, for example, is put into practical use for decreasing the wiring resistance. Unfortunately, Cu wiring also has problems such as stress-migration- or electromigration-induced degradation of reliability, a size effect-induced increase in electric resistivity, and embedding into fine via holes, and there has been a demand for wiring materials with lower resistance and higher current density tolerance.

Application of a carbon-based material such as a carbon nanotube and a graphene with an excellent physical property such as high current density tolerance, electric conduction property, thermal conductivity, and mechanical strength attracts attention as a next-generation wiring material expected to be low-resistance and highly reliable material. Especially, there have been studied wiring structures having lateral interlayer wiring formed using graphene. A method for forming a graphene wiring includes uniformly forming a graphene film on a substrate and patterning the graphene film into a wiring form or growing graphene on a catalyst layer that has been formed in a wiring pattern.

However, if a graphene wiring is made as thin as about 10 nm, the wiring may be turned into a semiconductor due to the quantum confinement effect of electrons, or the resistance of the wiring may increase due to the scattering effect at the edge.

An intercalation method including inserting a molecule between graphene sheets to convert graphene into a graphene intercalation compound is a promising method for reducing its resistance. The inserted molecule supplies electrons or holes to graphene to reduce its resistance. However, the intercalation treatment, which often uses a highly reactive material such as acid or halogen, can corrode materials composing a structure, such as a catalyst layer, under the wiring. Therefore, such a method is not suitable for treating a graphene wiring grown from a catalyst layer.

### BRIEF DESCRIPTION OF THE DRAWINGS

FIG. 1 is a schematic perspective view of a semiconductor device having a graphene wiring of an embodiment.

FIG. 2 is a schematic perspective view showing a method of manufacturing a graphene wiring of an embodiment.

FIG. 3 is a schematic perspective view showing a method of manufacturing a graphene wiring of an embodiment.

FIG. 4 is a schematic perspective view showing a method of manufacturing a graphene wiring of an embodiment.

### DETAILED DESCRIPTION

A graphene wiring includes a substrate, a catalyst layer on the substrate, a first graphene sheet layer on the catalyst layer, and a second graphene sheet layer on the first graphene layer. The second graphene layer comprises multilayer graphene sheets. The multilayer graphene sheets are intercalated with an atomic or molecular species.

A method of manufacturing a graphene wiring includes a first step of forming a catalyst layer on a substrate, a second step of forming a graphene layer on the catalyst layer comprising multilayer graphene sheets, a third step of removing part of the graphene layer, a fourth step of processing a component resulting from the third step with an atmosphere of a gas of an atomic or molecular species, and a fifth step of removing part of the graphene layer and part of the catalyst layer, which are not patterned in the third step.

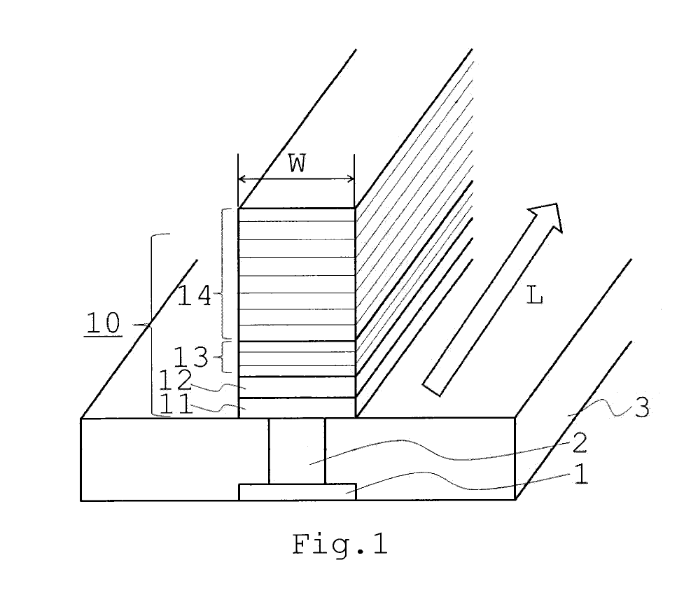

Hereinafter, a semiconductor device, a wiring, and a method of manufacturing them according to an embodiment will be described with reference to the drawings as needed. FIG. 1 is a perspective view of a semiconductor device 100 according to a first embodiment of the disclosure. The semiconductor device 100 includes a semiconductor substrate having an insulating film 3, a graphene wiring 10 on the insulating film 3, contact plugs 2 connected respectively to the lower and upper surfaces of the graphene wiring 10, and a conductive film 1 connected to the graphene wiring 10 via the contact plug 2. The contact plug 2 is formed in the contact layer insulating film 3.

The graphene wiring 10 includes a catalyst backing layer 11, a catalyst layer 12 formed on the catalyst backing layer 11, a first graphene layer 13 formed on the catalyst layer 12, and a second graphene layer 14 formed on the first graphene layer. In the graphene wiring 10, a current can flow along the longitudinal direction L of the wiring 10, for example, in the second graphene layer 14.

The catalyst backing layer 11 has a function as a co-Catalyst for growth of graphene constituting the first and second graphene layers 13 and 14. The catalyst backing layer 11 is made of, for example, a nitride or oxide of a metal such as Ti, Ta, Ru, or W. The catalyst backing layer 11 may have a multilayer structure having two or more different layers. The thickness of the catalyst backing layer is, for example, from 0.5 nm to 10 nm.

The catalyst layer 12 is made of a catalytic material capable of functioning as a catalyst for growth of graphene sheets constituting the first and second graphene layers 13 and 14. The catalyst layer 12 is formed on the insulating film 3 or the catalyst backing layer 11. The catalytic material for the catalyst layer 12 may be an elemental metal or alloy containing one or more of Co, Ni, Fe, Ru, Cu, and so on, or a carbide or other compounds of any of these metals or alloys. The thickness of the catalyst layer 12 is, for example, in a range of 5 nm to 20 nm.

The first graphene layer 13 is a wiring formed on the catalyst layer 12. The first graphene layer 13 includes a single layer of graphene sheet or multiple layers of graphene sheet including at most 20 layers. The number of such layers in the first graphene layer 13 can be adjusted by the manufacturing method. The graphene sheet may be a monolayer film of graphite and have a structure in which carbon atoms are arranged in a hexagonal lattice. The first graphene layer 13 has no atomic or molecular intercalant between layers of graphene sheet, except for an inevitable atomic or molecular species, whereas the second graphene layer 14 contains an atomic or molecular intercalant. The region from the first graphene layer 13 to the insulating film 3 does not contain the atomic or molecular species with which the second graphene layer 14 is intercalated. This is because in the step of intercalating the atomic or molecular species, the region from the first graphene layer 13 to the insulating film 3 is not exposed to a treatment gas containing the atomic or molecular species. Therefore, the catalyst backing layer 11 and the catalyst layer 12 are not corroded, and not only the graphene layer but also the whole of the graphene wiring 10 have low resistance. No corrosion of the metal films under the graphene layer is also advantageous in that the graphene wiring 10 is highly reliable.

The second graphene layer 14 is a wiring formed on the first graphene layer 13. For example, the second graphene layer 14 includes 10 to 200 layers of graphene sheet. The second graphene layer contains an atomic intercalant and/or a molecular intercalant between layers of graphene sheet. Such an atomic or molecular species is a material for increasing the conductivity of graphene. The atomic or molecular species to be intercalated between layers of graphene sheet is preferably a halogen such as F₂, Cl₂, Br₂, or I₂, an interhalogen compound such as IBr or ICl, a metal halide such as FeCl₃, CuCl₂, BF₄, or AsF₅, an acid such as sulfuric acid, nitric acid, or phosphoric acid, or an alkali metal or alkaline earth metal such as Li, Na, K, Mg, or Ca.

In the second graphene layer 14, electrons or holes are supplied to the graphene sheets to lower the resistance because an atomic or molecular species is intercalated between layers of graphene sheet. As the wiring width decreases, the resistance of graphene sheet increases due to conversion into semiconductor by the electron confinement effect or the scattering effect at the edge. However, the supply of electrons or holes to graphene can reduce these effects. In order to provide a fine-width wiring with low resistance as compared with conventional Cu wiring, the width W of the graphene wiring 10 is preferably in a range of 3 nm to 30 nm. The width of the graphene wiring can be checked using a transmission electron microscope (TEM).

In some cases, the resistance of the second graphene layer 14 can be higher in its thickness direction depending on the atomic or molecular intercalant species. In such cases, it is preferable that a conductive film or the like should be additionally provided to connect the highly conductive contact plug or the like to the second graphene layer 14.

As the width of the graphene wiring 10 decreases, the influence of the adverse factor mentioned above can become significant. In this embodiment, however, this drawback can be attenuated. Therefore, for example, even if the wiring width is as small as about 10 nm, the volume resistivity of the wiring can be made about one to two digits lower than that of graphene with no atomic or molecular intercalant. In this embodiment, for example, the graphene wiring can have a volume resistivity in a range of 10 μm·cm to 100 μm·cm.

Intercalation of an atomic or molecular species into multilayer graphene sheets will be specifically described using an example where Br₂ is intercalated into multilayer graphene sheets. Multilayer graphene with a thickness of about 400 nm is prepared and then exposed to Br₂ gas at saturated vapor pressure for 90 minutes to form a graphene wiring.

The resistance of the prepared graphene is measured by four-terminal method using four probes arranged in a square pattern on the prepared graphene. The volume resistivity of the graphene intercalated with Br₂ is in a range of 4 μΩ·cm to 8 μΩ·cm, whereas the volume resistivity of non-intercalated graphene is in a range of 36 μΩ·cm to 60 μΩ·cm. Therefore, the resistance (volume resistivity) of graphene wiring can be lowered by intercalating an atomic or molecular species into graphene.

Whether an atomic or molecular species is intercalated in graphene can be checked by a method including observing changes in Raman spectrum. More specifically, a specific atom- or molecule-derived peak, which is not detectable before the intercalation of the atomic or molecular species, can be checked, and graphene G peak splitting or wavenumber shift can be checked. If both phenomena are observed, it can be determined that an atomic or molecular species other than graphene is intercalated in graphene so that holes or electrons are supplied to graphene.

The semiconductor device of the embodiment may be of any type capable of being produced with the graphene wiring 10, such as an LSI. The conductive film 1 is, for example, a conductive member as a part of a semiconductor substrate for LSI or the like. The contact plug 2 is, for example, an interlayer wiring. The contact layer insulating film 3 is, for example, an interlayer wiring insulating film.

Next, a method of manufacturing a semiconductor device having the graphene wiring of the embodiment shown in the schematic perspective view of FIG. 1 will be described. In the embodiment, the semiconductor device may be of any type, and therefore, a method of manufacturing the graphene wiring 10 in the semiconductor device having the conductive film 1, the contact plug 2, and the insulating film 3 will be specifically described.

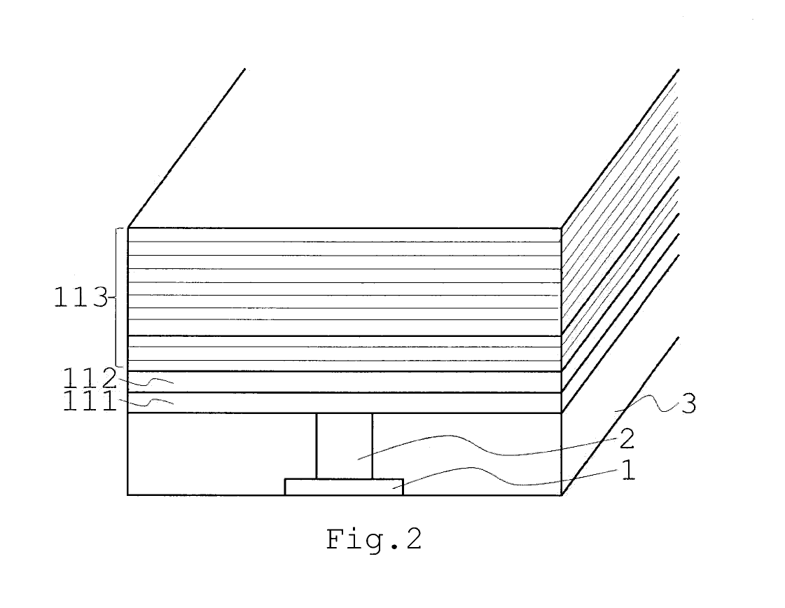

FIGS. 2 to 4 are schematic perspective views showing a method of manufacturing the semiconductor device 100 according to the embodiment of FIG. 1.

(First Step)

First, as shown in FIG. 2, a catalyst backing layer 111 is formed on the contact plug 2 and the contact layer insulating film 3. The catalyst backing layer 111 can be formed by chemical vapor deposition (CVD) or the like, in which each suitable material is deposited to form a film with an adjusted thickness. A catalyst layer 112 can also be formed in the same way as the catalyst backing layer 111.

(Second Step)

Subsequently, a graphene layer 113 is formed. For high-quality growth of graphene, the catalyst metal layer 112 is preferably subjected to a plasma pretreatment before the formation of the film. The plasma pretreatment is the step of forming the catalyst metal layer 112 into fine particles. The plasma pretreatment as the step of forming fine particles is performed using gas such as H₂, Ar, or N₂ at a treatment temperature of from 25° C. to 300° C. for a treatment time of from 30 seconds to 300 seconds. The treatment may be performed at a time using the gas, or the treatment may be performed by two or more separate steps using different gases.

Subsequently, using plasma CVD or the like, low-temperature ultrathin carbon film deposition and carbon deposition are performed as needed on the part having undergone the step of forming fine particles, so that the component of FIG. 2 is formed. Both the low-temperature ultrathin carbon film deposition and the carbon deposition do not always have to be performed, and only one of them may be performed. The low-temperature ultrathin carbon film deposition includes performing a treatment with a plasma containing carbonaceous gas such as methane at a temperature of from 200° C. to 400° C. for a short time such as about 30 seconds. The carbon deposition includes performing deposition using a plasma containing carbonaceous gas such as methane at a temperature of from 300° C. to 700° C. A remote plasma is preferably used in order to obtain a high-quality graphene film.

(Third Step)

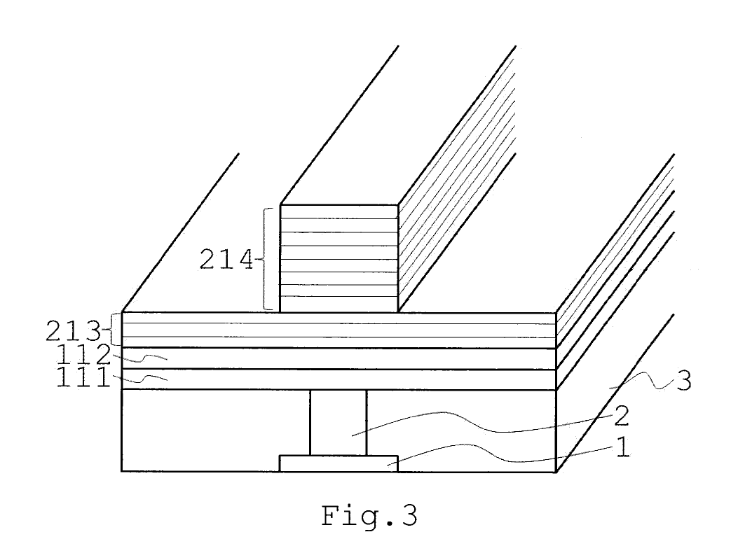

Subsequently, as shown in FIG. 3, part of the graphene layer 113 is patterned, for example, using a combination of lithography and reactive ion etching (RIE). The patterned graphene layer 214 has a wiring pattern. The wiring pattern may be any desired pattern. The unpatterned part is a graphene layer 213 covering the whole of the catalyst layer.

(Fourth Step)

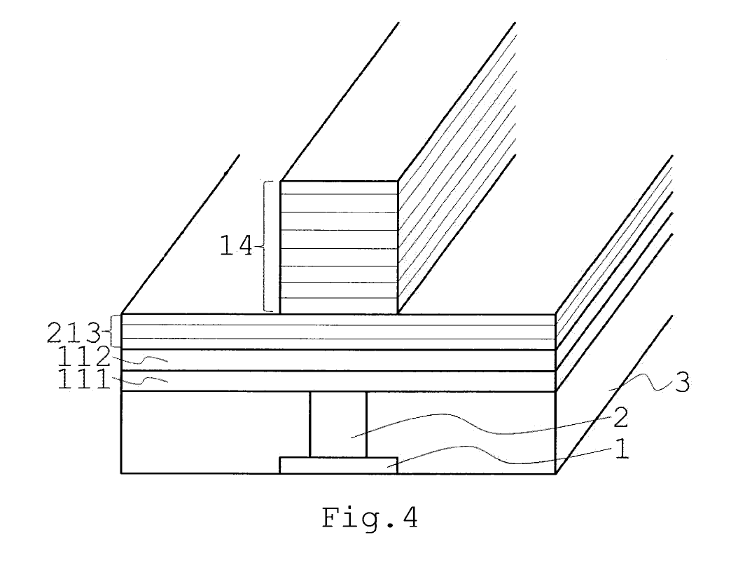

Subsequently, as shown in FIG. 4, the graphene layer 214 is subjected to an intercalation treatment with an atomic or molecular species, so that the graphene layer 214 is converted into a graphene intercalation compound layer as the second graphene layer 14. The component is subjected to the intercalation treatment in an atmosphere of a raw material gas of the atomic or molecular species. Depending on the physical properties or amount of the atomic or molecular intercalant species, this treatment is preferably a heat treatment. In this step, the catalyst layer 112 and the catalyst backing layer 111, which are covered with the graphene layer 213, are protected from the highly reactive material used in the intercalation treatment. The atomic or molecular species is intercalated between layers of graphene sheet in the second graphene layer 14. Depending on the atomic or molecular intercalant species, part of the atoms or molecules may be physically or chemically bonded to or in contact with the graphene sheets. The edge of the substrate or any other part which is not covered with the graphene layer 213 may be sealed with resin or other materials so that the catalyst layer 12 or the catalyst backing layer 11 can be further protected.

(Fifth Step)

Subsequently, using a combination of lithography and RIE, the graphene layer 213, the catalyst layer 112, and the catalyst backing layer 111 are patterned into the same or substantially the same shape as the second graphene layer 14, so that a first graphene layer 13, a catalyst layer 12, and a catalyst backing layer 11 are obtained. The semiconductor device 100 having the graphene wiring 10 shown in FIG. 1 is obtained.

The graphene wiring according to the embodiment provides a low-resistance wiring because the graphene intercalation compound used to form the wiring has an electron or hole density higher than that of graphene. In addition, during the intercalation treatment, the graphene layer is used as a protective layer for the catalyst layer and other structures under the wiring, so that they can be prevented from corroding.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A graphene wiring, comprising:
a substrate;
a catalyst layer on the substrate;
a first graphene sheet layer on the catalyst layer; and
a second graphene sheet layer on the first graphene layer, wherein
the second graphene layer comprises multilayer graphene sheets, and
the multilayer graphene sheets are intercalated with an atomic or molecular species.

2. The wiring according to claim 1, wherein a width of the first and second graphene sheet layers is in a range of 3 nm to 30 nm.

3. The wiring according to claim 1, wherein the atomic or molecular species is at least one selected from F₂, Cl₂, Br₂, I₂, IBr, ICl, FeCl₃, CuCl₂, BF₄, AsF₅, sulfuric acid, nitric acid, phosphoric acid, Li, Na, K, Mg, and Ca.

4. The wiring according to claim 1, wherein the first graphene layer comprises single graphene sheet or multilayer graphene sheets.

5. A method of manufacturing a graphene wiring, the method comprising:
a first step of forming a catalyst layer on a substrate;
a second step of forming a graphene layer on the catalyst layer, wherein the graphene layer comprises multilayer graphene sheets;
a third step of removing part of the graphene layer;
a fourth step of processing a component resulting from the third step with an atmosphere of a gas of an atomic or molecular species; and
a fifth step of removing part of the graphene layer and part of the catalyst layer, which are not patterned in the third step.

6. The method according to claim 5, wherein a width of the graphene wiring is in a range of 3 nm to 30 nm.

7. The method according to claim 5, wherein the atomic or molecular species is at least one selected from F₂, Cl₂, Br₂, I₂, IBr, ICl, FeCl₃, CuCl₂, BF₄, AsF₅, sulfuric acid, nitric acid, phosphoric acid, Li, Na, K, Mg, and Ca.
